(19) United States
(12) Patent Application Publication
(10) Pub. No.: US 2013/0115870 A1
(43) Pub. Date: May 9, 2013

(54) CHASSIS OF ELECTRONIC DEVICE

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/411,612

(22) Filed: Mar. 4, 2012

(30) Foreign Application Priority Data
Nov. 9, 2011 (TW) 100140831

(51) Int. Cl. H05K 5/02

(52) U.S. Cl. 454/184; 165/80.2

(57) ABSTRACT

A chassis includes two opposite sidewalls, a first vent wall connected between corresponding ends of the sidewalls, and a second vent wall connected between the sidewalls and close to an inner surface of the first vent wall. The first vent wall defines a number of first vents extending along a first direction. The second vent wall defines a number of second vents extending along a second direction different from the first direction.

### BACKGROUND

1. Technical Field

The present disclosure relates to a chassis of an electronic device.

2. Description of Related Art

Electronic components of electronic devices, such as central processing units, generate a lot of heat, leading to high temperatures in the electronic devices. Vents may be included to allow cooling airflow through the devices, but they often have to be small to prevent electromagnetic interference (EMI), which keeps cooling efficiency low.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of a chassis of an electronic device.

FIGS. 2 and 3 are different sectional views of the chassis of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

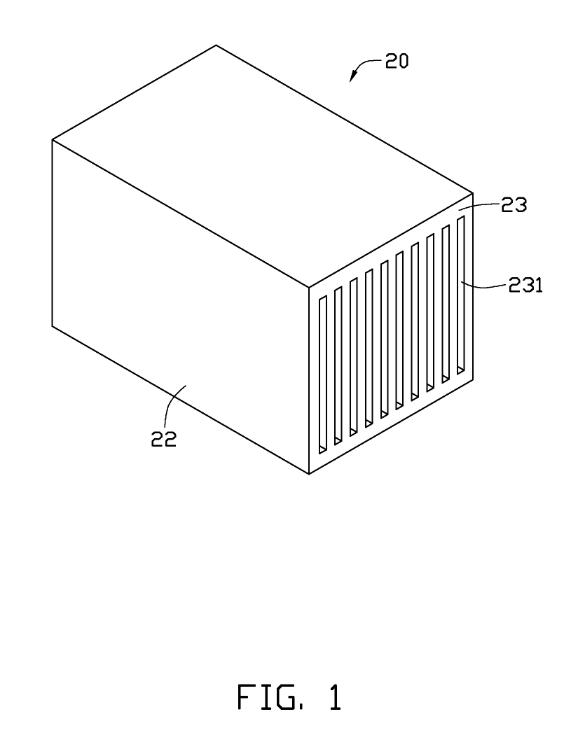

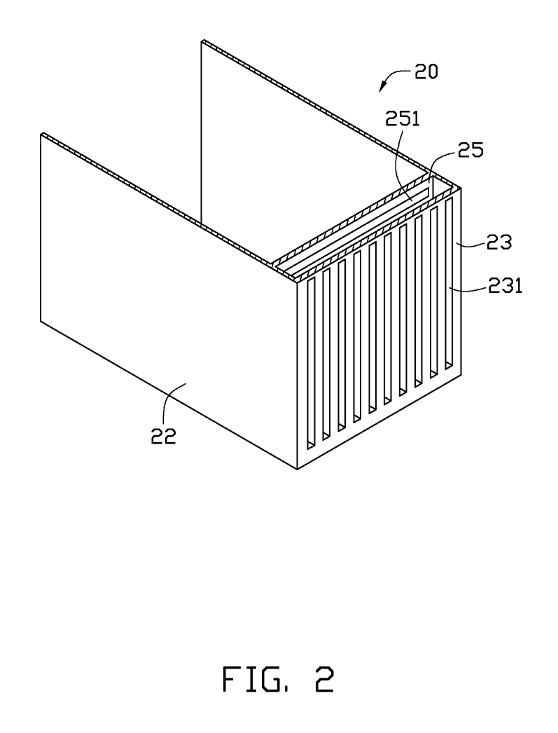

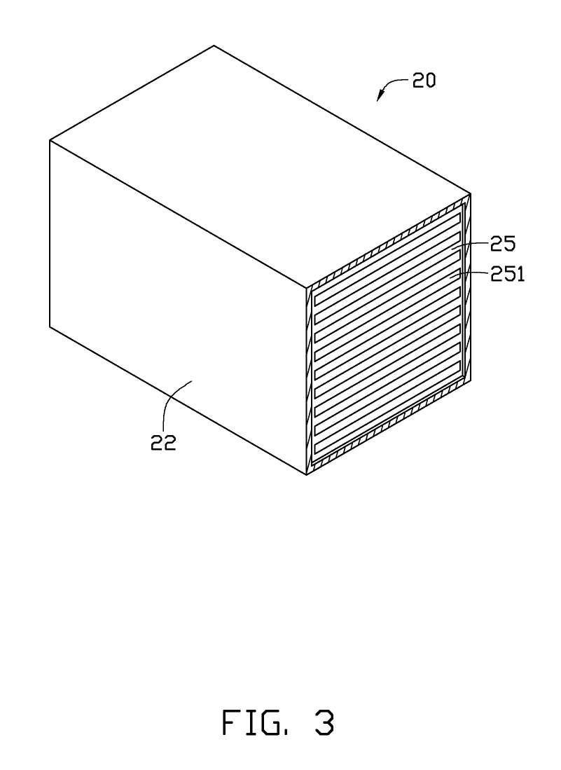

Referring to FIGS. 1-3, an exemplary embodiment of a chassis 20 of an electronic device, such as a computer, includes two opposite sidewalls 22, a first vent wall 23 perpendicularly connected between first ends of the sidewalls 22, and a second vent wall 25 parallel to the first vent wall 23 and perpendicularly connected between the sidewalls 22. The second vent wall 25 is close to an inner surface of the first vent wall 23. In the embodiment, the distance from the second vent wall 25 to the first vent wall 23 is about 3 millimeters (mm) A plurality of long first vents 231 is defined in the first vent wall 23, substantially parallel to the sidewalls 22. A plurality of long second vents 251 is defined in the second vent wall 25, substantially perpendicular to the sidewalls 22.

The long air vents 231, 251 allow for a greater volume of air to flow through the chassis 20 for greater cooling efficiency, but because they extend along perpendicular directions direct paths for escape or entry of electromagnetic waves are minimized and thereby electromagnetic interference (EMI) is minimized.

In a second embodiment, a plurality of vents substantially perpendicular to the sidewalls 22 is defined in the first vent wall 23, and a plurality of vents substantially parallel to the sidewalls 22 is defined in the second vent wall 25. In other embodiments, the first vents and the second vents may be acutely angled relative to each other, such that an angle between the first vents and the second vents ranges from about 45 degrees to about 90 degrees, such as 45 degrees, 60 degrees, or 80 degrees.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A chassis comprising:
two opposite sidewalls;
a first vent wall connected between corresponding ends of the sidewalls, the first vent wall defining a plurality of long first vents extending along a first direction; and
a second vent wall connected between the sidewalls and close to an inner surface of the first vent wall, the second vent wall defining a plurality of long second vents extending along a second direction different from the first direction.

2. The chassis of claim 1, wherein the distance from the first vent wall to the second vent wall is about 3 millimeters.

3. The chassis of claim 1, wherein an angle between the first direction and the second direction ranges from about 45 degrees to about 90 degrees.

4. The chassis of claim 3, wherein the first direction is substantially parallel to the sidewalls, and the second direction is substantially perpendicular to the sidewalls.

5. The chassis of claim 3, wherein the first direction is substantially perpendicular to the sidewalls, and the second direction is substantially parallel to the sidewalls.
